(19) United States
(12) Patent Application Publication
(10) Pub. No.: US 2015/0195907 A1
(43) Pub. Date: Jul. 9, 2015

(54) MULTILAYERED SUBSTRATE AND METHOD OF MANUFACTURING THE SAME

(71) Applicant: SAMSUNG ELECTRO-MECHANICS CO., LTD., Suwon (KR)

(72) Inventors: Yul Kyo CHUNG, Yongin (KR); Seung Eun Lee, Sungnam (KR); Yee Na Shin, Suwon (KR); Doo Hwan Lee, Daejeon (KR)

(73) Assignee: SAMSUNG ELECTRO-MECHANICS CO., LTD., Suwon (KR)

(21) Appl. No.: 14/509,603

(22) Filed: Oct. 8, 2014

(30) Foreign Application Priority Data
Jan. 9, 2014 (KR) 10-2014-0002838

(51) Int. Cl. H05K 1/02; H05K 1/11; H05K 3/00; H05K 1/03

(52) U.S. Cl. CPC H05K 1/0298; H05K 1/0274; H05K 1/0306; H05K 1/115; H05K 3/0017; H05K 2201/0108

(57) ABSTRACT

A multilayered substrate includes an insulating layer or core comprised of a glass material and having a light transmittance of about 50% or less; circuit pattern layers or parts respectively formed on the surfaces of the insulating layer or core; and a build-up part covering a surface of the insulating layer or core and one of the circuit pattern layers

### CROSS-REFERENCE TO RELATED APPLICATIONS

This application claims the foreign priority benefit under 35 U.S.C. Section 119 of Korean Patent Application Serial No. 10-2014-0002838, filed on Jan. 9, 2014, in the Korean Intellectual Property Office, which is hereby incorporated by reference in its entirety into this application.

### BACKGROUND

1. Field

Embodiments of the present invention relate to a multilayered substrate and a method of manufacturing the same.

2. Description of the Related Art

In response to trends in electronic devices toward lightness, miniaturization, high-speed, multi-function, and high-performance, technologies in which a plurality of wiring layers are formed on a printed circuit board (PCB), such as multilayered substrate technologies, have been developed.

Particularly, semiconductors used for mobile electronic devices have been packaged and have been released in a form in which a plurality of packages are coupled. One example is an arrangement in which an application processor (AP) installed on a smart phone forms a package on package (POP) together with a memory element.

Meanwhile, the performance of mobile semiconductors such as the AP has been improving. In order to efficiently implement the improved performance, improvement in communication speed between the AP and the memory element should be supported.

In order to improve the communication speed within the package or between the packages, impedance of the communication line should be decreased. In order to decrease impedance of the communication line, a method of increasing wiring width may be considered. However, this method has a limitation in that wiring density is decreased as the wiring width is increased.

Impedance of the communication line may also be decreased by implementing slimness of the package to shorten a wiring distance. However, as the package is slimmed, a bending phenomenon comes to the forefront with a severe problem.

The above-mentioned bending phenomenon is referred to as warpage and as the package or the multilayered substrate is formed of various materials having different thermal expansion coefficients, the warpage has intensified.

According to the related art, in order to decrease the above-mentioned warpage, a method in which an insulating layer is formed of a material having strong rigidity has been used. For example, US 2009/0294161 A1 discloses an example of decreasing warpage by using a core layer containing glass fiber and US 2012/0192413 A1 discloses an example of using glass core.

### SUMMARY

One aspect of the present invention is to provide a multilayered substrate capable of decreasing warpage, implementing slimness, and decreasing a defect rate.

Another aspect of the present invention is to provide a method of manufacturing a multilayered substrate capable of decreasing warpage, implementing slimness, and decreasing a defect rate.

The present invention is not limited to addressing the above-mentioned considerations. That is, other benefits different from or in addition to those mentioned above, including those that can be understood by those skilled in the art, are within the scope of the disclosure.

According to an exemplary embodiment of the present invention, there is provided a multilayered substrate, including: a first insulating layer comprised of a glass material and having light transmittance of 1% to 50%; a first circuit pattern layer formed on one surface of the first insulating layer; a second circuit pattern layer formed on the other surface of the first insulating layer; a first build-up part covering one surface of the first insulating layer and the first circuit pattern layer; and a second build-up part covering the other surface of the first insulating layer and the second circuit pattern layer.

Light transmittance may be expressed by It/Io, wherein Io may represent intensity of light irradiated toward one surface of the first insulating layer, and It may represent intensity of light passing through the first insulating layer to thereby be transmitted to the other surface of the first insulating layer.

At least one surface of the first insulating layer may have a root mean square (RMS) surface roughness value of about 0.1 to about 5 μm measured in a sampling range of about 50 pm or more.

The first build-up part and the second build-up part may have the number of built-up layers different from each other.

The first insulating layer may include a cavity penetrating between one surface and the other surface of the first insulating layer or a recess portion recessed in one surface or the other surface of the first insulating layer, and the multilayered substrate may further include: an electronic component having at least portion inserted into the cavity or the recess portion and at least one external electrode formed on at least one surface thereof.

The first insulating layer may contain a colorant.

A surface of the first insulating layer may be coated with a colored resin.

The first circuit pattern layer or the second circuit pattern layer may include: an adhesive film including a material selected from titanium or chrome; and a plating film formed on a surface of the adhesive film.

According to another exemplary embodiment of the present invention, there is provided a multilayered substrate including a core, circuit pattern parts formed on both surfaces of the core, and a build-up part covering the circuit pattern parts and a surface of the core, wherein the core is made of a glass including an opaque portion and has light transmittance of about 1% to about 50%.

A thickness from an upper surface of the core to an upper surface of the multilayered substrate may be different from a thickness from a lower surface of the core to a lower surface of the multilayered substrate.

According to another exemplary embodiment of the present invention, there is provided a method of manufacturing a multilayered substrate including a core made of a glass material, circuit pattern parts formed on both surfaces of the core, and a build-up part covering the circuit pattern parts and a surface of the core, the method including: embossing-processing at least one surface of the core.

The embossing-processing of at least one surface of the core may be performed by providing an etching solution to the at least one surface of the core.

The embossing-processing of at least one surface of the core may be performed so that the at least one surface of the core has a RMS surface roughness value of a range of about 0.1 μm to about 5 μm measured in a sampling range of about 50 μm or more.

According to another exemplary embodiment of the present invention, a multilayered substrate includes: an insulating layer comprised of a glass material and having a light transmittance of about 50% or less for light incident on one of two opposite surfaces of the insulating layer; circuit pattern layers respectively formed on opposite surfaces of the insulating layer; and a build-up part covering a surface of the insulating layer and one of the circuit pattern layers.

Additional aspects and/or advantages will be set forth in part in the description which follows and, in part, will be apparent from the description, or may be learned by practice of the invention.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 is a cross-sectional view schematically showing a multilayered substrate according to an exemplary embodiment of the present invention;

FIG. 2 is a cross-sectional view schematically showing a multilayered substrate according to another exemplary embodiment of the present invention;

FIG. 3 is a schematically enlarged view of part A of FIG. 1;

FIG. 4A is a view schematically showing a state in which a first insulating layer is provided according to an exemplary embodiment of the present invention;

FIG. 4B is a view schematically showing a state in which a cavity is formed in the first insulating layer according to an exemplary embodiment of the present invention;

FIG. 4C is a view schematically showing a state in which a first circuit pattern layer and a second circuit pattern layer are formed on the first insulating layer according to an exemplary embodiment of the present invention;

FIG. 4D is a view schematically showing a state in which an electronic component is inserted into a cavity of the first insulating layer according to an exemplary embodiment of the present invention;

FIG. 4E is a view schematically showing a state in which a first upper build-up insulating layer and a first lower build-up insulating layer are formed on the first insulating layer according to an exemplary embodiment of the present invention;

FIG. 4F is a view schematically showing a state in which a conductive pattern is further formed according to an exemplary embodiment of the present invention; and

FIG. 4G is a view schematically showing a state in which build-up insulating layers are further formed according to an exemplary embodiment of the present invention.

### DESCRIPTION OF EMBODIMENTS

Various advantages and features of the present invention and technologies accomplishing thereof will become apparent from the following description of exemplary embodiments with reference to the accompanying drawings. However, the present invention may be modified in many different forms and it should not be limited to exemplary embodiments set forth herein. These exemplary embodiments may be provided so that this disclosure will be thorough and complete, and will fully convey the scope of the invention to those skilled in the art. Like reference numerals denote like elements throughout the description.

Terms used in the present specification are for explaining exemplary embodiments rather than limiting the present invention. Unless specifically mentioned otherwise, a singular form includes a plural form in the present specification. The word “comprise” and variations such as “comprised of,” “comprises” or “comprising,” will be understood to imply the inclusion of stated constituents, steps, operations and/or elements but not the exclusion of any other constituents, steps, operations and/or elements.

For simplification and clearness of illustration, a general configuration scheme will be shown in the accompanying drawings, and a detailed description of the feature and the technology well known in the art will be omitted in order to prevent a discussion of exemplary embodiments of the present invention from being unnecessarily obscure. Additionally, components shown in the accompanying drawings are not necessarily shown to scale. For example, sizes of some components shown in the accompanying drawings may be exaggerated as compared with other components in order to assist in understanding of exemplary embodiments of the present invention. Like reference numerals on different drawings will denote like components, and similar reference numerals on different drawings will denote similar components, but are not necessarily limited thereto.

In the specification and the claims, terms such as “first”, “second”, “third”, “fourth”, and the like, if any, will be used to distinguish similar components from each other and be used to describe a specific sequence or a generation sequence, but is not necessarily limited thereto. It may be understood that these terms are compatible with each other under an appropriate environment so that exemplary embodiments of the present invention to be described below may be operated in a sequence different from a sequence shown or described herein. Likewise, in the present specification, in the case in which it is described that a method includes a series of steps, a sequence of these steps suggested herein is not necessarily a sequence in which these steps may be executed. That is, any described step may be omitted and/or any other step that is not described herein may be added to the method.

In the specification and the claims, terms such as “left”, “right”, “front”, “rear”, “top, “bottom”, “over”, “under”, and the like, if any, do not necessarily indicate relative positions that are not changed, but are used for description. It may be understood that these terms are compatible with each other under an appropriate environment so that exemplary embodiments of the present invention to be described below may be operated in a direction different from a direction shown or described herein. A term “connected” used herein is defined as being directly or indirectly connected in an electrical or non-electrical scheme. Targets described as being “adjacent to” each other may physically contact each other, be close to each other, or be in the same general range or region, in the context in which the above phrase is used. Here, a phrase “in an exemplary embodiment” means the same exemplary embodiment, but is not necessarily limited thereto.

Hereinafter, a configuration and an acting effect of exemplary embodiments of the present invention will be described in more detail with reference to the accompanying drawings.

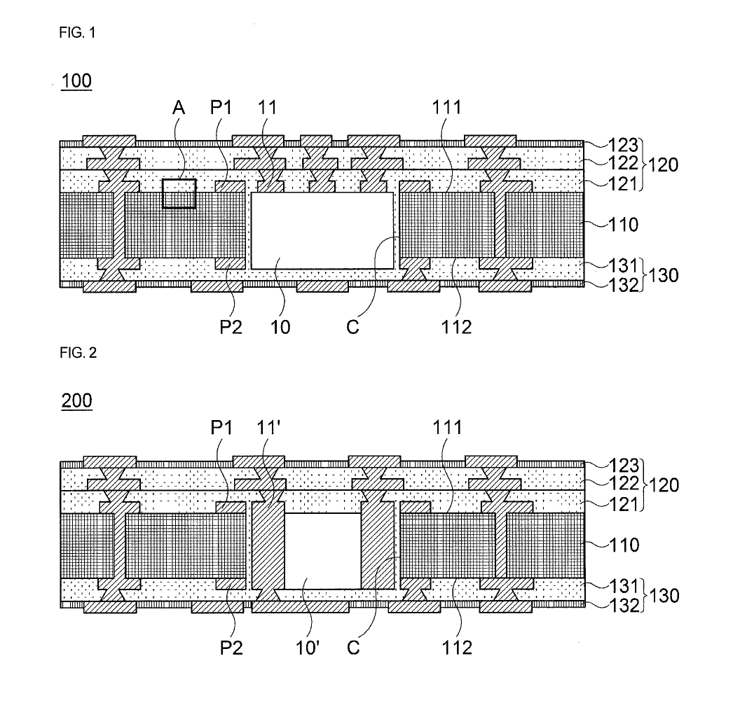

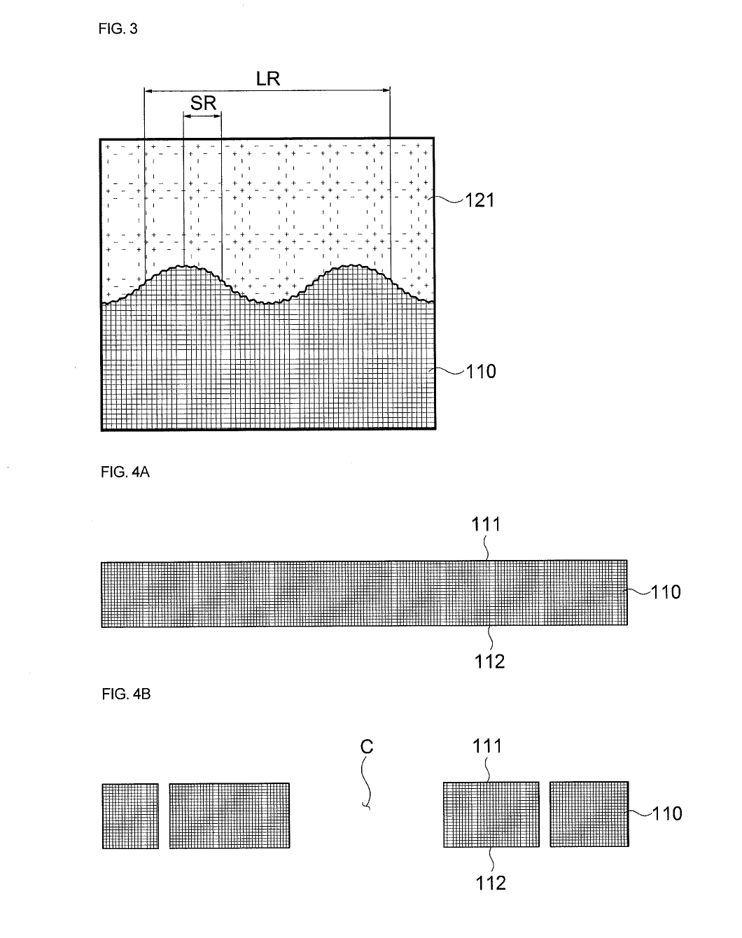

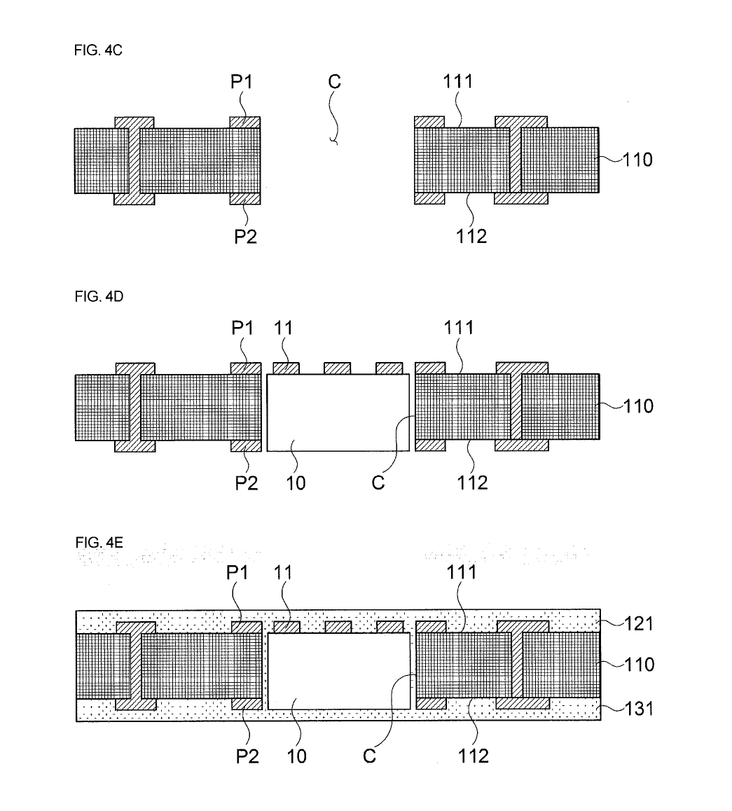

FIG. 1 is a cross-sectional view schematically showing a multilayered substrate 100 according to an exemplary embodiment of the present invention. FIG. 2 is a cross-sectional view schematically showing a multilayered substrate 100 according to another exemplary embodiment of the present invention. FIG. 3 is a schematically enlarged view of part A of FIG. 1.

Referring to FIGS. 1 through 3, a multilayered substrate 100 according to an exemplary embodiment of the present invention may include a first insulating layer 110, a first circuit pattern layer P1, a second circuit pattern layer P2, a first build-up part 120, and a second build-up part 130.

According to an exemplary embodiment of the present invention, the first insulating layer 110 may serve as a core. That is, the first insulating layer 110 may serve to reinforce rigidity of the multilayered substrate 100 to thereby decrease a warpage phenomenon.

Therefore, the first insulating layer 110 may be made of a material having strong rigidity. According to an exemplary embodiment of the present invention, the first insulating layer 110 may be made of a glass material.

According to an exemplary embodiment of the present invention, the first insulating layer may have the first circuit pattern layer P1 formed on one surface 111 thereof and the second circuit pattern layer P2 formed on the other surface 112 thereof. Here, the first circuit pattern layer P1 and the second circuit pattern layer P2 may be referred to as a circuit pattern part. In addition, the first circuit pattern layer P1 and the second circuit pattern layer P2 may include an adhesive film contacting a surface of the first insulating layer 110 and a plating film formed on a surface of the adhesive film. In this case, the adhesive film may be made of a metal material such as titanium, chrome, or the like and the plating film may be made of a metal material such as a copper, or the like.

As a process of forming the first circuit pattern layer P1 and the second circuit pattern layer P2 on the surface of the first insulating layer 110, a typical exposure and development process may be used. According to an exemplary embodiment of the present invention, the first insulating layer 110 may be made of a glass material. In this situation, since a typical glass material is transparent, light provided to one surface 111 of the first insulating layer to expose the first insulating layer during a forming process of the first circuit pattern layer P1 may arrive at the other surface 112 of the first insulating layer to thereby influence a region in which the second circuit pattern layer P2 is to be formed. That is, even in the case in which pattern shapes of the first circuit pattern layer P1 and the second circuit pattern layer P2 are implemented to be different from each other, the light which is irradiated to implement a shape of the first circuit pattern layer P1 may affect or change a property of a photoresist present on the region in which the second circuit pattern layer P2 is to be formed. As a result, the second circuit pattern layer P2 might not be formed in a desired shape.

Further, the light may also be irradiated even in an inspection process of inspecting whether the first circuit pattern layer P1 or the second circuit patter layer P2 is accurately implemented on the surface of the insulating layer 110 according to a design. Even in this process, since the first insulating layer 110 is made of the glass material, the irradiated light may pass through the first insulating layer 110. In addition, the light passing through the insulating layer 110 may decrease precision in the inspection process.

According to an exemplary embodiment of the present invention, light transmittance of the first insulating layer 110 may be in a range of about 1% to about 50%. Therefore, since the influence of the light irradiated toward one surface 111 of the first insulating layer on the other surface 112 of the first insulating layer may be decreased, the above-mentioned problems which may be caused from the exposure or inspection process may be solved.

Here, light transmittance may mean a ratio of intensity of light transmitted to the other surface 112 of the first insulating layer to intensity of light irradiated toward one surface 111 of the first insulating layer. That is, assuming that the intensity of the light irradiated toward one surface 111 of the first insulating layer is lo and the intensity of the light passing through the first insulating layer 110 to be transmitted to the other surface 112 of the first insulating layer is It, light transmittance may be It/Io.

Meanwhile, according to an exemplary embodiment of the present invention, light transmittance of the first insulating layer 110 may be in a range of about 1% to about 50% by containing a colorant in the first insulating layer 110. In this case, various materials may be used as the colorant. For example, a complex compound containing transition metal ion, or the like may be contained in a glass component.

In addition, according to another exemplary embodiment of the present invention, a colored resin may be coated on one surface 111 of the first insulating layer or the other surface 112 of the first insulating layer.

According to still another exemplary embodiment of the present invention, surface roughness may be formed on one surface 111 of the first insulating layer or the other surface 112 of the first insulating layer.

A relatively more “transparent” material means that the light irradiated toward the solid losses relatively less energy while passing through the solid. When light is irradiated on the surface of the solid, energy loss may be caused while the light is absorbed into the solid, is reflected from the solid, or is scattered. Here, as the surface roughness of the solid is large, a scattering level of the light becomes large.

Meanwhile, in the exposure process or optical inspection process, visible ray, i-line (365 nm), h-line (405 nm), g-line (436 nm), KrF excimer laser (248 nm), ArF laser (193 nm), or the like may be used.

According to an exemplary embodiment of the present invention, in order for the light irradiated toward one surface 111 of the first insulating layer or the other surface 112 of the first insulating layer 112 to have a light transmittance of about 1% to about 50%, the surface roughness may be about 0.1 μm or more.

Although the surface roughness may be defined by several ways, the present specification defines the surface roughness by using a root mean square (RMS) surface roughness measured in a predetermined sampling range.

Referring to FIG. 3, a state in which the surface roughness is formed on one surface of the first insulating layer 111 may be understood. An abbreviation LR indicated in FIG. 3 means a long range and SR means a short range.

The light scattering may be separately considered in each of a haze phenomenon and a phenomenon in which contrast is decreased.

Here, the haze phenomenon means a phenomenon in which a phase is distorted due to a scattering at a low angle. In addition, the phenomenon in which contrast is decreased may be caused by a scattering at a large angle. In addition, the haze phenomenon may be caused by a large scale roughness and the contrast decrease by the large angle scattering may be caused by a small scale roughness.

Optical devices used for an optical inspection or an exposure in a process of manufacturing a substrate tend to sensitively react to the low angle scattering by the haze phenomenon. Therefore, in order to usefully use the surface roughness in inspecting the substrate, forming a circuit by the exposure, or the like, management of the large scale roughness may be particularly important. Therefore, according to an exemplary embodiment of the present invention, for the surface roughness on one surface 111 of the first insulating layer or the other surface 112 of the first insulating layer, it may be defined that the RMS surface roughness value measured in the sampling range of about 50 μm or more becomes about 0.1 μm or more.

Meanwhile, as the surface roughness of the first insulating layer 110 is increased, light transmittance becomes low. However, if the surface roughness becomes too large, it may affect precision of the first circuit pattern layer P1 or the second circuit pattern layer P2 formed on the surface of the first insulating layer 110. That is, if the surface roughness of the first insulating layer 110 becomes too large, it may interfere with a decrease of a wiring width or a pattern pitch of the first circuit pattern layer P1 or the second circuit pattern layer P2. Therefore, according to an exemplary embodiment of the present invention, the RMS surface roughness value measured in the sampling range of about 50 μm or more may become about 5.0 μm or less.

As result, the first circuit pattern layer P1 or the second circuit pattern layer P2 may be precisely formed on one surface 111 of the first insulating layer 111 or the other surface 112 of the first insulating layer, and precision of the inspection process may also be improved.

Particularly, compared to the case of containing the colorant in the first insulating layer 110, the case of forming the surface roughness on the surface of the first insulating layer 110 does not affect permittivity of the first insulating layer 110 and may also be advantageous in view of production costs in implementing the first insulating layer 110.

In addition, compared to the case of coating the colored resin on the surface of the first insulating layer 110, the case of forming the surface roughness on the surface of the first insulating layer 110 may be advantageous to slim the multilayered substrate 100.

In addition, when an appropriate surface roughness is implemented on the surface of the first insulating layer 110, adhesion between the material forming the first circuit pattern layer P1 or the second circuit pattern layer P2 and the first insulating layer 110 may be increased.

Meanwhile, referring back to FIG. 1, according to an exemplary embodiment of the present invention, the first build-up part 120 may be provided on one surface 111 of the first insulating layer and the first circuit pattern layer P1. In addition, the second build-up part 130 may be provided on a lower surface of the first insulating layer 110 and the second circuit pattern layer P2.

Here, the first build-up part 120 may include a first upper build-up insulating layer 121 and the second build-up part 130 may include a first lower build-up insulating layer 131.

In addition, according to an exemplary embodiment of the present invention, the first build-up part 120 and the second build-up part 130 may have differ from each other in the number of built-up layers included in the respective build-up part. For example, the first build-up part 120 may further include a second upper build-up insulating layer 122 and a third upper build-up insulating layer 123, and the second build-up part 130 may further include a second lower build-up insulating layer 132. In this case, the third upper build-up insulating layer 123 and the second lower build-up insulating layer 132 may be a solder resist layer.

Since the multilayered substrate 100 according to the exemplary embodiment of the present invention improves rigidity thereof by including the first insulating layer 110 made of the glass material, warpage may be decreased even though the build-up parts formed on both surfaces based on the first insulating layer 110 are implemented in an asymmetric structure.

Meanwhile, the first insulating layer 110 may be provided with a cavity C or a recess portion (not shown), where a portion or an entire of an electronic component 10 may be inserted into the cavity C or the recess portion. In addition, the electric component 10 may be provided with an external electrode 11.

FIG. 1 shows a case in which the electronic component 10, which is active element having the external electrodes 11 formed on one surface thereof, is embedded in the multilayered substrate 100, and FIG. 2 shows a case in which an electronic component 10′, which is a passive element such as a capacitor, or the like, is embedded in a multilayered substrate 200.

In addition, although not shown, an outer surface of the first build-up part 120 may be connected to other elements and an outer surface of the second build-up part 130 may be coupled to other substrate structures such as a mother board, and the like. That is, as shown in FIG. 1, in the case in which the electronic component 10 is an application processor (AP), a memory element is coupled to the outer surface of the first build-up part 120, such that a kind of package on package (POP) may be implemented and this POP may be mounted on the mother board.

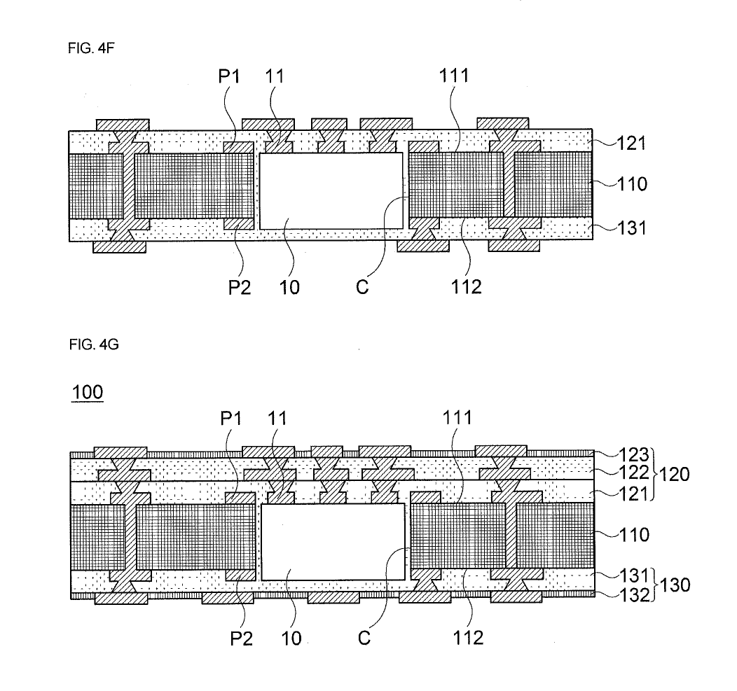

Hereinafter, a method of manufacturing a multilayered substrate 100 according to an exemplary embodiment of the present invention will be described with reference to FIGS. 4A and 4G.

FIG. 4A is a view schematically showing a state in which a first insulating layer 110 is provided according to an exemplary embodiment of the present invention. Referring to FIG. 4A, the first insulating layer 110 made of a glass material having light transmittance of about 1% to about 50% may be provided. In this case, the first insulating layer 110 may be an insulating layer in which light transmittance is adjusted by containing the colorant, coating the colored resin on the surface thereof, or forming the surface roughness as described above.

Meanwhile, the surface roughness of the first insulating layer 110 may be formed by an embossing process.

According to an exemplary embodiment of the present invention, the embossing process may be implemented by a mechanical processing method such as a sand blasting method, or the like.

According to another exemplary embodiment of the present invention, the embossing process may be implemented by providing an etching solution to the first insulating layer 110 to thereby perform a chemical etching process.

When the first insulating layer 110 is formed in a thin type, it is advantageous to perform the chemical etching process rather than the mechanical processing method in improving production yield of the first insulating layer 110.

FIG. 4B is a view schematically showing a state in which a cavity C is formed in the first insulating layer 110 according to an exemplary embodiment of the present invention. Referring to FIG. 4B, the cavity C may be formed in the first insulating layer 110 and may be implemented by a method such as a laser drilling method, or the like.

In addition, although not shown, a recess portion, which does not penetrate through the first insulating layer 110, may be formed.

FIG. 4C is a view schematically showing a state in which a first circuit pattern layer P1 and a second circuit pattern layer P2 are formed on the first insulating layer 110 according to an exemplary embodiment of the present invention. Referring to FIG. 4C, the first circuit pattern layer P1 may be formed on one surface 111 of the first insulating layer and the second circuit pattern layer P2 may be formed on the other surface 112 of the first insulating layer. In this case, in the case in which the surface roughness is formed by performing an embossing process for one surface 111 of the first insulating layer or the other surface 112 of the first insulating layer, an exposure process for implementing the circuit pattern, an inspection process inspecting whether the circuit pattern is appropriately formed, or the like may be precisely performed.

Meanwhile, the first circuit pattern layer P1 and the second circuit pattern layer P2 may be electrically connected to each other by a via penetrating through the first insulating layer 110.

FIG. 4D is a view schematically showing a state in which an electronic component 10 is inserted into the cavity C of the first insulating layer 110 according to an exemplary embodiment of the present invention. Referring to FIG. 4D, an entire or a portion of the electronic component 10 may be inserted into the cavity C.

FIG. 4E is a view schematically showing a state in which a first upper build-up insulating layer 121 and a first lower build-up insulating layer 131 are formed on the first insulating layer 110 according to an exemplary embodiment of the present invention. Referring to FIG. 4E, the first upper build-up insulating layer 121 and the first lower build-up insulating layer 131 may be made of a typical insulating material.

FIG. 4F is a view schematically showing a state in which a conductive pattern is further formed according to an exemplary embodiment of the present invention and FIG. 4G is a view schematically showing a state in which build-up insulating layers are further formed according to an exemplary embodiment of the present invention.

Referring to FIGS. 4F and 4G, it may be appreciated that the conductive patterns are further formed on a first upper build-up insulating layer 121 and a first lower build-up insulating layer 131, and a second upper build-up insulating layer 122, a third upper build-up insulating layer 123, a second lower build-up insulating layer 132, and the like may be further formed on the first upper build-up insulating layer 121 and the first lower build-up insulating layer 131.

According to the exemplary embodiments of the present invention, warpage of the multilayered substrate may be decreased, slimness thereof may be implemented, and the defect rate thereof may be decreased.

Although a few embodiments have been shown and described, it would be appreciated by those skilled in the art that changes may be made in these embodiments without departing from the principles and spirit of the invention, the scope of which is defined in the claims and their equivalents.

What is claimed is:

1. A multilayered substrate, comprising:
a first insulating layer comprised of a glass material and having a light transmittance of about 1% to about 50%;
a first circuit pattern layer formed on one surface of the first insulating layer;
a second circuit pattern layer formed on the other surface of the first insulating layer;
a first build-up part covering one surface of the first insulating layer and the first circuit pattern layer; and
a second build-up part covering the other surface of the first insulating layer and the second circuit pattern layer.

2. The multilayered substrate according to claim 1, wherein the light transmittance is in terms of It/Io,
wherein Io represents intensity of light irradiated toward one surface of the first insulating layer, and It represents intensity of light passing through the first insulating layer to thereby be transmitted to the other surface of the first insulating layer.

3. The multilayered substrate according to claim 2, wherein at least one surface of the first insulating layer has a root mean square (RMS) surface roughness value of about 0.1 μm to about 5 μm measured in a sampling range of about 50 μm or more.

4. The multilayered substrate according to claim 2, wherein the first build-up part and the second build-up part are each comprised of different respective numbers of built-up layers.

5. The multilayered substrate according to claim 4, wherein
the first insulating layer includes a cavity penetrating between one surface and the other surface of the first insulating layer or a recess portion recessed in one surface or the other surface of the first insulating layer, and
the multilayered substrate further comprises an electronic component having at least portion inserted into the cavity or the recess portion and at least one external electrode formed on at least one surface thereof.

6. The multilayered substrate according to claim 4, wherein each of the build-up layers of the first build-up part and of the second build-up part has a via passing therethrough.

7. The multilayered substrate according to claim 2, wherein the first insulating layer contains a colorant.

8. The multilayered substrate according to claim 2, wherein the first insulating layer includes a colored resin layer at a surface of the first insulating layer.

9. The multilayered substrate according to claim 2, wherein the first circuit pattern layer or the second circuit pattern layer includes:
an adhesive film including at least one material selected from titanium and chrome; and
a plating film formed on a surface of the adhesive film.

10. A multilayered substrate comprising:
a core, at least partially opaque, comprised of a glass and the core having a light transmittance of about 1% to about 50%;
circuit pattern parts respectively formed on opposite surfaces of the core; and
a build-up part covering a surface of the core and one of the circuit pattern parts.

11. The multilayered substrate according to claim 10, wherein a thickness from an upper surface of the core to an upper surface of the multilayered substrate is different from a thickness from a lower surface of the core to a lower surface of the multilayered substrate.

12. A method of manufacturing a multilayered substrate including a core made of a glass material, circuit pattern parts formed on both surfaces of the core, and a build-up part covering the circuit pattern parts and a surface of the core, the method comprising:
embossing-processing at least one surface of the core.

13. The method according to claim 12, wherein the embossing-processing of the at least one surface of the core is performed by providing an etching solution to at least one surface of the core.

14. The method according to claim 12, wherein the embossing-processing of at least one surface of the core is performed so that the at least one surface of the core has a root mean square (RMS) surface roughness value in a range of about 0.1 μm to about 5 μm measured in a sampling range of about 50 μm or more.

15. A multilayered substrate comprising:
an insulating layer comprised of a glass material and having a light transmittance of about 50% or less for light incident on one of two opposite surfaces of the insulating layer;
circuit pattern layers respectively formed on the opposite surfaces of the insulating layer; and
a build-up part covering a surface of the insulating layer and one of the circuit pattern layers.

16. The multilayered substrate according to claim 15, wherein at least one surface of the first insulating layer has a surface roughness having a root mean square (RMS) surface roughness value of about 0.1 μm to about 5 μm measured in a sampling range of about 50 μm or more.

17. The multilayered substrate according to claim 16, wherein the surface roughness of the at least one surface is in contact with the circuit pattern layer formed on the at least one surface.
